(19) United States
(12) Patent Application Publication
(10) Pub. No.: US 2026/0206583 A1
(43) Pub. Date: Jul. 16, 2026

(54) COOLING DEVICE AND COOLING SYSTEM

(71) Applicant: Infineon Technologies Austria AG, Villach (AT)

(72) Inventors: Uwe KIRCHNER, Witra (AT); Paulus Petrus Bernardus ARTS, Villach (AT); Julian TREU, München (DE); Benjamin Florian STEINACHER, Villach (AT)

(21) Appl. No.: 19/419,221

(22) Filed: Dec. 15, 2025

(30) Foreign Application Priority Data
Jan. 10, 2025 (DE) 102025100707.1

(51) Int. Cl. H10W 40/20; H10W 40/73

(52) U.S. Cl. CPC H10W 40/242; H10W 40/73

(57) ABSTRACT

A cooling device is configured for cooling electrical components, the device includes a first heat transfer portion and a second heat transfer portion, wherein the first heat transfer portion is configured to conduct heat from a heat source to the second heat transfer portion, the first heat transfer portion including a vapor chamber of an electrically isolating material, configured to be coupled to the heat source, an electrically isolating liquid contained inside the vapor chamber, a heat spreading element forming at least in part one sidewall of the vapor chamber, and wherein the second heat transfer portion is at least in part in thermal contact with the heat spreading element.

### CROSS-REFERENCE TO RELATED APPLICATION

This application claims priority to Germany Patent Application No. 102025100707.1 filed on Jan. 10, 2025, the content of which is incorporated by reference herein in its entirety.

### TECHNICAL FIELD

The present disclosure relates to a cooling device and a cooling system configured for cooling an electrical component, preferably a high voltage carrying discrete semiconductor device.

### BACKGROUND

With the increase of power density in modern day's discrete semiconductor devices, an increased need for cooling emerges. However, air cooling is no longer sufficient with increased power density. Consequently, new ways of cooling need to be explored in conjunction with high voltage carrying discrete semiconductor devices.

Moreover, there is currently no way for equipping existing discrete semiconductor devices and modules with new ways of cooling. Further, in future semiconductor device concepts cooling will be part of the power electronic manufacturing. This allows for miniaturization, e.g., die shrinking by enhancing heat spreading.

For these and other reasons, there is a need for the present disclosure.

### SUMMARY

According to a first aspect of the present disclosure a cooling device is configured for cooling an electrical component, the device including a first heat transfer portion and a second heat transfer portion, wherein the first heat transfer portion is configured to conduct heat from the electrical component to the second heat transfer portion, the first heat transfer portion including a vapor chamber of an electrically isolating material, configured to be coupled to the electrical component, an electrically isolating or non insulating liquid contained inside the vapor chamber, a heat spreading element forming at least in part one sidewall of the vapor chamber, and wherein the second heat transfer portion is at least in part in thermal contact with the heat spreading element.

According to the first aspect, an electrical component being a heat source can be cooled by a sequentially stacked arrangement of heat exchangers, namely the first and second heat transfer portions. The electrical component may be a semiconductor device but the cooling device is not limited to semiconductor devices. Produced heat inside the semiconductor device may be dissipated and routed by a layer stack inside the device. A chip may be attached to a lead frame by an adhesive or may be directly soldered to the lead frame. The semiconductor device may include an exposed die pad, that is an exposed portion of the lead frame or, alternatively and optionally, a thermal interface material, TIM, as an exposed surface. At least one portion of the lead frame or the thermal interface material may be exposed at an upper side of the semiconductor device, to conduct heat produced at the junction to an outside of the semiconductor device.

Heat generated by the semiconductor device may be transferred by the first heat transfer portion, which is a phase change cooler, to the second heat transfer portion. By employing a phase change cooler heat can be very efficiently lead away from the semiconductor device.

By using an electrically isolating fluid inside the first heat transfer portion, no thermal interface material at the bottom side of the first heat transfer portion is necessary. Direct heat transfer is very efficient. Heat transfer from the first to the second heat exchanger is achieved by a heat spreading element. The heat spreading element may be part either of the first or the second heat exchanger or of both. The heat spreading element may also be simply a heat conducting element. The second heat exchanger may be a cold plate or a liquid cooler, which may be connected to more external coolers or standard heatsinks.

According to the first aspect, a semiconductor package is equipped with a modular or integrated thermosyphon and liquid heatsink. Heat can be transferred by the first heat exchanger (thermosyphon) to the cascaded second heat exchanger (liquid chamber). The semiconductor device may be formed integrally with the cooling device during additive manufacturing.

In an implementation, the cooling device merely includes the first heat exchanger.

Particularly, the vapor chamber is in thermal contact with a heat conducting interface of the heat source, that is the electrical component. That means, the first heat transfer portion is in direct contact with an underlying heat source.

In an implementation, the electrical component is a semiconductor device and wherein the vapor chamber is in thermal contact with the semiconductor device at a metal interface or an exposed die pad of the semiconductor device. The semiconductor device may include a chip, that is a semiconductor die, producing heat during operation. The highest temperature of the chip is at the junction and may be referred to as the junction temperature. If the includes an exposed die pad no thermal interface material (TIM) may be necessary, which allows for better manufacturability. The vapor chamber may be formed out of a single piece, that is, may be formed integrally, with a housing or mold body of the semiconductor device. Consequently, the first heat transfer portion may be manufactured in a single molding step together with the mold body of the semiconductor device.

In an implementation, the vapor chamber is of a long-term stable electric isolating material including a wick structure, particularly a groove structure a sintered structure or a screen structure. Particularly, the wick structures are configured to return the liquid from the heat spreading element towards the heat source. The wick structures may support a circulation of the electrically isolating liquid inside the vapor chamber.

For the first heat transfer portion to transfer heat, the electrically isolating liquid may be a saturated liquid and its vapor (gas phase). The saturated liquid vaporizes and travels to a condenser (as will be detailed below), where it is cooled and turned back to a saturated liquid. The condensed liquid is returned to the heat source which acts as an evaporator, using the wick structure exerting a capillary action on the liquid phase of the electrically isolating liquid. The wick structures may include sintered metal powder, screen, and grooved wicks, which have a series of grooves parallel to the pipe axis.

In an implementation, the wick structure is arranged at a connection portion between the heat spreading element and a bottom surface of the vapor chamber, the bottom surface of the vapor chamber being in thermal contact with the heat source.

Particularly, the vapor chamber and the heat spreading element are configured to hermetically seal and include the electrically isolating liquid, wherein the heat spreading element is a condenser element.

The condenser element may be located above the evaporator, which may be the bottom surface of the vapor chamber. In a gravitational field, gravity can return the liquid. In this case, the first heat transfer portion is a thermosiphon. The liquid is guided back to the bottom surface through the wick structures after condensing on the top side (heat spreader) to evaporate again there. However, the wick structures may support this process, as they are arranged at sidewalls which in a thermosyphon form the connection portions between the condenser element and the evaporator.

Particularly, the heat spreading element is a metal plate or a thermal interface material, TIM. The heat spreading element may be configured to conduct heat away from the vapor chamber and hence assume lower temperature than the gas phase of the electrically isolating liquid contained in the vapor chamber. Thereby the heat spreading element functions as the condenser element of the thermosyphon.

In an implementation, the second heat transfer portion includes a liquid chamber, the liquid chamber including a channel configured for liquid cooling, wherein the channel is in thermal contact with the heat spreading element and configured to be streamed through by a heat transport liquid. The second heat transfer portion may be a fluid/liquid heat exchanger to transport and thus remove heat conducted to the second heat transfer portion.

In an implementation, the liquid chamber includes distribution elements forming the channel and configured for guiding the flow of the heat transport liquid through the channel, particularly wherein the liquid chamber includes turbulator elements. The channel inside the liquid chamber may be formed by the distribution elements, which may be protrusions, walls, fins or the like. The channel may be formed by the elements to guide the flow of the heat transport liquid past a major surface of the heat spreading element. The heat spreading element may be seen as a heat source for the second heat transfer portion. A major surface of the heat spreading element may be a lateral surface, or a surface configured for significant heat transfer. Moreover, the liquid chamber may include turbulator elements configured to evoke turbulences in the heat transport liquid in the channel.

Turbulences increase the Reynolds Number, Re, which makes up for better thermal transfer. Both the turbulator elements and the distribution elements may be formed integrally with the liquid chamber.

In an implementation, the heat spreading element includes protrusions or fins. The protrusions or fins may take the function of turbulator elements or of additional guiding or distribution elements. The protrusions or fins may be formed integrally with the heat spreading element.

In an implementation, the electrically isolating liquid includes a phase change temperature according to the implemented semiconductor in the semiconductor device. A preferred Phase change temperature, that is a boiling point is around the operation point of the semiconductor device. A preferred boiling point of the electrically isolating liquid is from 80-100° C. Depending on the heat source, a suitable fluid can be chosen.

According to a second aspect of the disclosure a system for cooling a semiconductor device is provided, the system including the cooling device of the first aspect of the disclosure, a semiconductor package and a fluid connector for connecting the second heat transfer portion to a tube system.

In an implementation the system further includes a pump configured to circulate the heat transport liquid in the tube system and through the second heat transfer portion. A pump is optional, because the system may work as a purely passive system without the pump. However, the pump may be advantageous to adjust the flow rate of the heat transport liquid through the second heat transfer portion. By adjusting the flow rate, the amount of heat removed from the second heat transfer portion may be adjusted, which makes the system adaptable to various heat conditions.

In an implementation system includes a cooler connected to the pump and/or the second heat transfer portion by the tube system. The cooler may be a plate, or a board cooler or a combination of several plate coolers. Moreover, the cooler may be an immersion cooler. The cooler may also be referred to as a third heat transfer portion or third heat exchanger.

In an implementation the system further includes a fan configured to provide an airflow to the cooler. If the cooler is a plate cooler, that is an air cooler, heat transfer from the cooler to the surroundings may be enhanced by providing an air flow produced by the fan through ribs or plates of the cooler. Moreover, if the cooler is an immersion cooler, a flow medium of the fan may also be a liquid.

In a further implementation, the system includes at least one temperature sensing element arranged at the vapor chamber and/or at the second heat transfer portion and/or at the semiconductor package. The system may further include a controller configured to receive at least one temperature sensing signal from the temperature sensing element, and to generate a first control signal to be provided to the pump, and/or a second control signal to be provided to the fan. Thereby, effective temperature control at the first heat transfer portion is enabled. However, the temperature sensing element may also be attached to other parts of the system and/or to other parts of the device. For example, the temperature sensing element may be attached to the second heat transfer portion or directly to the junction at the semiconductor device.

### BRIEF DESCRIPTION OF THE DRAWINGS

Example implementations of the disclosure are described with reference to the following figures:

FIG. 1 shows a schematic implementation of the first aspect of the present disclosure.

FIG. 2 shows an expanded view of the implementation according to FIG. 1.

FIG. 3 shows a system according to the second aspect of disclosure.

### DESCRIPTION

In the following detailed description, reference is made to the accompanying drawings. The drawings show specific examples in which the implementation may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”.

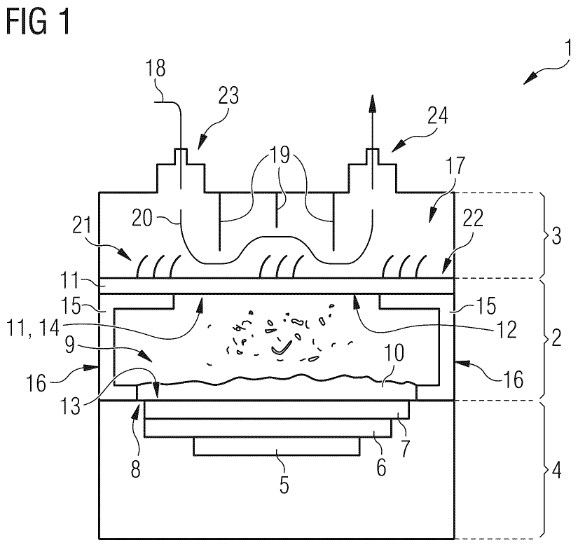

FIG. 1 shows a cooling device 1. The cooling device 1 comprises a first heat transfer portion 2 and a second heat transfer portion 3. The first heat transfer portion 2 is arranged atop a semiconductor device 4.

The semiconductor device 4 is a heat source. The heat is produced inside the semiconductor device 4 by a semiconductor die 5. The semiconductor die 5 may be part of a layer stack, wherein an outermost part of the layer stack may form an exposed portion of the semiconductor device 4. The semiconductor die 5 may be bonded or attached to a first layer 6, which may be a lead frame or an insulating adhesive. The first layer may be coupled to a second layer 7 which may be a lead frame or thermal interface material, TIM. The layer stack comprises the first layer 6 and the second layer 7 but may also comprise more layers.

Heat produced by the semiconductor die 5 during operation is conducted by the first and second layers 6,7 to the exposed portion of an uppermost surface of the semiconductor device 8.

The first transfer portion 2 is coupled to the upper surface of the semiconductor device 8. The upper surface of the semiconductor device 8 is a heat conducting interface of the heat source. Particularly, the heat conducting interface is a metal interface or an exposed die pad of the semiconductor device 4. As the first heat transfer portion 2 is in direct contact with the heat source and is hence configured to transfer heat from the heat source to further devices.

The first heat transfer portion 2 is a first heat exchanger and is embodied as a vapor chamber 9. The first heat transfer portion 2 is of an electrically isolating material, which is a long-term stable electrically isolating material. The electrically isolating material may hence be an inorganic material, such as glass or ceramic. The vapor chamber 9 is filled with a suitable liquid, wherein the liquid is an electrically isolating liquid 10. The electrically isolating liquid 10 is contained in the vapor chamber 9 and hermetically sealed therein.

The first heat transfer element 2 further comprises a heat spreading element 11. The heat spreading element 11 may be a metal plate. The heat spreading element 11 forms an upper lid or uppermost inner surface 12 opposite a bottom surface 13 of the vapor chamber 9.

The heat spreading element 11 functions as a condenser element 14. That is, the electrically isolating liquid 10 evaporating at the bottom surface of the vapor chamber 13 will condense at the condenser element 14.

The first heat transfer portion 2 further comprises a wick structure 15. The wick structure 15 is configured to guide condensed liquid to the bottom surface of the vapor chamber 13 from the condenser element 14, or to at least support this process. Therefore, the wick structure 15 is arranged at a connection portion 16, that is, the side wall of the vapor chamber 9, connecting the bottom surface 13 of the vapor chamber 9 to the heat spreading element 11. The wick structure 15 may also cover a part of the bottom surface 13 of the vapor chamber 9 and part of the heat spreading element 11.

The second heat transfer portion 3 is arranged atop the first heat transfer portion 2 and is in thermal contact with at least portions of the heat spreading element 11. That is, the second heat transfer portion 3 is configured to receive heat from the first heat transfer portion 2. The second heat transfer portion 3 may also be referred to as a second heat exchanger. Particularly, the second heat transfer portion 3 comprises a liquid chamber 17. The liquid chamber 17 is configured to enable a flow of a heat transport liquid 18 past a surface of the liquid chamber 17, wherein a surface of the liquid chamber is in contact with a major surface of the heat spreading element 11. To enable the flow of heat transport liquid 18 through the liquid chamber 17, the liquid chamber 17 comprises distribution elements 19. The distribution elements 19 form a channel 20 through which the heat transport liquid may flow.

Further the liquid chamber 17 may comprise turbulator elements 21. The turbulator elements 21 are fins or protrusions. Moreover, the heat spreading element 11 itself may form a bottom surface 22 of the liquid chamber 17. The turbulator elements 21 may be integral parts of the heat spreading element 11 and thus may protrude vertically from the bottom surface 22 of the liquid chamber 17 into the channel 20.

The second heat transfer portion 3 comprises an inlet connector 23 and an outlet connector 24.

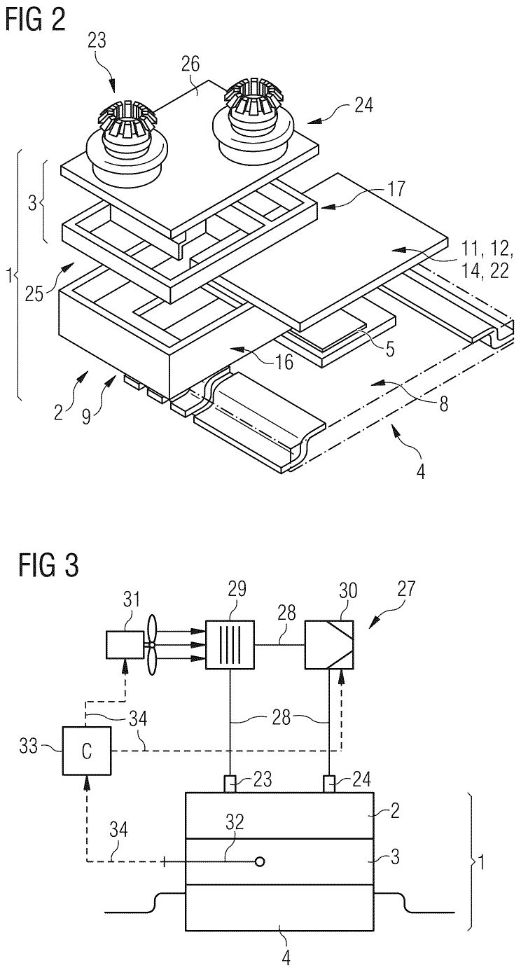

FIG. 2 shows an expanded view of a possible implementation of the schematic cooling device 1 of FIG. 1. The cooling device 1 is shown as being mounted atop a semiconductor device 4. The semiconductor device 4 comprises the semiconductor die 5 which is located at the topside of the semiconductor device 4 and has at least one portion being coplanar with the uppermost surface 8 of the semiconductor device 4. The first heat transfer portion 2 is shown as being attachable to the semiconductor device 4. The vapor chamber 9 comprises a housing made of an insulating plastic material. The vapor chamber may be attachable to the uppermost surface 8 of the semiconductor device 4. Heat spreading element 11 forms a part/wall/surface/lid of the vapor chamber 9. Heat spreading element 11 is a metal plate and acts as a condenser element 14. Sidewalls of the housing may be identified with connection portions 16. The first heat transfer elements 2 may be manufactured by an additive manufacturing method such as 3D printing. The bottom surface 22 of the liquid chamber 17 is formed by the heat spreading element 11. Hence the first heat transfer portion 2 and the second heat transfer portion 3 are stacked sequentially and thermally connected by the heat spreading element 11.

The second heat transfer portion 3 comprises a frame 25. The frame forms at least sidewalls/surrounding walls of the liquid chamber 17. Further, the second heat transfer portion 3 comprises an upper element 26. The upper element 26 forms a lid of the liquid chamber 17. The upper element comprises both the inlet connector 23 and the outlet connector 24.

The semiconductor device 4 may be a standard molded package with a metal interface for the vapor chamber 9. In the vapor chamber 9 the liquid will change the state to gas.

The vapor chamber 9 is made of a long term stable electric isolating material including e.g., a wick structure. An additional TIM (electrical insulator) is not required. The mechanical properties will cover creepage and clearance. The chamber can be 3D printed.

The liquid inside the vapor chamber 9 is long term electric isolating with a phase change temperature point according to the implemented semiconductor.

The vapor chamber 9 is closed by a metal plate, where the gas changes the state to liquid.

The package 4 can be combined with a liquid chamber 17 (integrated cold plate) or combined with standard heat sinks.

Several of these modules can be combined in a modular way in one single cooling concept.

FIG. 3 shows a system 27 according to the second aspect of the disclosure. The system 27 comprises the cooling device 1, the cooling device 1 including the semiconductor device 4.

The cooling device 1 is communicatively coupled via the inlet connector 23 and the outlet connector 24 to a tube system 28. The tube system 28 is configured for circulating the heat transport liquid.

The tube system 28 connects the cooling device 1 to further, peripheral devices. The system further comprises a cooler 29 through which the heat transport liquid is guided. The system further comprises a pump 30 configured to adjust a flow rate of the heat transport liquid through the cooler 29.

The system 27 further comprises a fan 31. The fan 31 is configured to generate an airflow (or a flow of any cooling fluid) through the cooler 29. A temperature sensing element 32 is located at the second heat transfer portion 3 and connected to a controller 33. Alternatively liquid-to-liquid heat exchangers may be used as cooler 29. In this case the fan 31 is not required.

The controller 33 is configured to receive a sensor signal via signaling path 34. The controller 33 is further configured to generate at least one control signal based on the sensor signal provided by the temperature sensing element 32. A first control signal may be output to the fan 31 to adjust an airflow through the cooler 29. A second control signal may be output from the controller 33 to the pump 30 to adjust the flow rate of the heat transport liquid through the second heat transfer portion 3 and through the cooler 29. The flow rate of the heat transport liquid through the second heat transfer portion 3 may also be constant, while the airflow through the cooler 29 generated by the fan is adjustable.

### Aspects

The following provides an overview of some Aspects of the present disclosure:

Aspect 1: A cooling device configured for cooling an electrical component, the cooling device comprising: a first heat transfer portion and a second heat transfer portion; wherein the first heat transfer portion is configured to conduct heat from the electrical component to the second heat transfer portion, the first heat transfer portion comprising: a vapor chamber of an electrically isolating material, configured to be coupled to the electrical component; an electrically isolating liquid contained inside the vapor chamber; and a heat spreading element forming at least in part one sidewall of the vapor chamber, and wherein the second heat transfer portion is at least in part in thermal contact with the heat spreading element.

Aspect 2: The cooling device of Aspect 1, wherein the electrical component is a semiconductor device, and wherein the vapor chamber is in thermal contact with the semiconductor device at a metal interface or at an exposed die pad of the semiconductor device.

Aspect 3: The cooling device of any of Aspects 1-2, wherein the vapor chamber is of an electrically isolating material including a wick structure, particularly a groove structure, a sintered structure or a screen structure.

Aspect 4: The cooling device of Aspect 3, wherein the wick structure is arranged at a connection portion between the heat spreading element and a bottom surface of the vapor chamber, the bottom surface of the vapor chamber being in thermal contact with the electrical component.

Aspect 5: The cooling device of any of Aspects 1-4, wherein the heat spreading element is a metal plate or a thermal interface material.

Aspect 6: The cooling device of any of Aspects 1-5, wherein the vapor chamber and the heat spreading element are configured to seal and comprise the electrically isolating liquid, wherein the heat spreading element is a condenser element.

Aspect 7: The cooling device of any of Aspects 1-6, wherein the second heat transfer portion comprises a liquid chamber, the liquid chamber comprising a channel configured for liquid cooling, wherein the channel is in thermal contact with the heat spreading element and configured to be streamed through by a heat transport liquid.

Aspect 8: The cooling device of Aspect 7, wherein the liquid chamber comprises distribution elements forming the channel and configured for guiding a flow of the heat transport liquid through the channel, particularly wherein the liquid chamber comprises turbulator elements.

Aspect 9: The cooling device of any of Aspects 1-8, wherein the heat spreading element comprises protrusions or fins.

Aspect 10: The cooling device of Aspect 2, wherein the electrically isolating liquid comprises a phase change temperature according to an implemented semiconductor in the semiconductor device.

Aspect 11: A system for cooling a semiconductor device, the system comprising: a semiconductor device; cooling device configured for cooling the semiconductor device, the cooling device comprising: a first heat transfer portion and a second heat transfer portion, wherein the first heat transfer portion is configured to conduct heat from the semiconductor device to the second heat transfer portion, the first heat transfer portion comprising: a vapor chamber of an electrically isolating material, configured to be coupled to the semiconductor device; an electrically isolating liquid contained inside the vapor chamber; and a heat spreading element forming at least in part one sidewall of the vapor chamber, and wherein the second heat transfer portion is at least in part in thermal contact with the heat spreading element; and a fluid connector for connecting the second heat transfer portion to a tube system.

Aspect 12: The system of Aspect 11, further comprising: a pump configured to circulate a heat transport liquid in the tube system and through the second heat transfer portion.

Aspect 13: The system of Aspect 12, further comprising: a cooler connected to the pump and/or to the second heat transfer portion by the tube system.

Aspect 14: The system of Aspect 13, comprising a fan configured to provide an airflow to the cooler.

Aspect 15: The system of Aspect 14, further comprising: at least one temperature sensing element arranged at the vapor chamber and/or at the second heat transfer portion and/or at a semiconductor package of the semiconductor device; and a controller configured to receive at least one temperature sensing signal from the at least one temperature sensing element, and generate a first control signal to be provided to the pump, and/or a second control signal to be provided to the fan.

Aspect 16: A system configured to perform one or more operations recited in one or more of Aspects 1-15.

Aspect 17: An apparatus comprising means for performing one or more operations recited in one or more of Aspects 1-15.

### LIST OF REFERENCE SIGNS

1. cooling device
2. first heat transfer portion
3. second heat transfer portion
4. semiconductor device
5. semiconductor die
6. first layer
7. second layer
8. uppermost surface of the semiconductor device
9. vapor chamber
10. electrically isolating liquid
11. heat spreading element
12. upper surface/lid
13. bottom surface of the vapor chamber
14. condenser element
15. wick structure
16. connection portion
17. liquid chamber
18. flow of heat transport liquid
19. distribution elements
20. channel
21. turbulator elements
22. bottom surface of the liquid chamber
23. inlet connector
24. outlet connector
25. frame
26. upper element
27. system
28. tube system
29. cooler
30. pump
31. fan
32. temperature sensing element
33. controller
34. signaling path

1. A cooling device configured for cooling an electrical component, the cooling device comprising:
a first heat transfer portion and a second heat transfer portion; wherein the first heat transfer portion is configured to conduct heat from the electrical component to the second heat transfer portion, the first heat transfer portion comprising:
a vapor chamber of an electrically isolating material, configured to be coupled to the electrical component;
an electrically isolating liquid contained inside the vapor chamber; and
a heat spreading element forming at least in part one sidewall of the vapor chamber, and
wherein the second heat transfer portion is at least in part in thermal contact with the heat spreading element.

2. The cooling device of claim 1, wherein the electrical component is a semiconductor device, and
wherein the vapor chamber is in thermal contact with the semiconductor device at a metal interface or at an exposed die pad of the semiconductor device.

3. The cooling device of claim 1, wherein the vapor chamber is of an electrically isolating material including a wick structure, particularly a groove structure, a sintered structure or a screen structure.

4. The cooling device of claim 3, wherein the wick structure is arranged at a connection portion between the heat spreading element and a bottom surface of the vapor chamber, the bottom surface of the vapor chamber being in thermal contact with the electrical component.

5. The cooling device of claim 1, wherein the heat spreading element is a metal plate or a thermal interface material.

6. The cooling device of claim 1, wherein the vapor chamber and the heat spreading element are configured to seal and comprise the electrically isolating liquid, wherein the heat spreading element is a condenser element.

7. The cooling device of claim 1, wherein the second heat transfer portion comprises a liquid chamber, the liquid chamber comprising a channel configured for liquid cooling, wherein the channel is in thermal contact with the heat spreading element and configured to be streamed through by a heat transport liquid.

8. The cooling device of claim 7, wherein the liquid chamber comprises distribution elements forming the channel and configured for guiding a flow of the heat transport liquid through the channel, particularly wherein the liquid chamber comprises turbulator elements.

9. The cooling device of claim 1, wherein the heat spreading element comprises protrusions or fins.

10. The cooling device of claim 2, wherein the electrically isolating liquid comprises a phase change temperature according to an implemented semiconductor in the semiconductor device.

11. A system for cooling a semiconductor device, the system comprising:
a semiconductor device;
cooling device configured for cooling the semiconductor device, the cooling device comprising:
a first heat transfer portion and a second heat transfer portion,
wherein the first heat transfer portion is configured to conduct heat from the semiconductor device to the second heat transfer portion, the first heat transfer portion comprising:
a vapor chamber of an electrically isolating material, configured to be coupled to the semiconductor device;
an electrically isolating liquid contained inside the vapor chamber; and
a heat spreading element forming at least in part one sidewall of the vapor chamber, and
wherein the second heat transfer portion is at least in part in thermal contact with the heat spreading element; and
a fluid connector for connecting the second heat transfer portion to a tube system.

12. The system of claim 11, further comprising:
a pump configured to circulate a heat transport liquid in the tube system and through the second heat transfer portion.

13. The system of claim 12, further comprising:
a cooler connected to the pump and/or to the second heat transfer portion by the tube system.

14. The system of claim 13, comprising a fan configured to provide an airflow to the cooler.

15. The system of claim 14, further comprising:
at least one temperature sensing element arranged at the vapor chamber and/or at the second heat transfer portion and/or at a semiconductor package of the semiconductor device; and
a controller configured to receive at least one temperature sensing signal from the at least one temperature sensing element, and generate a first control signal to be provided to the pump, and/or a second control signal to be provided to the fan.
